(19) United States
(12) Patent Application Publication
(10) Pub. No.: US 2014/0157892 A1
(43) Pub. Date: Jun. 12, 2014

(54) MEMS ELEMENT, ELECTRONIC DEVICE, ALTIMETER, ELECTRONIC APPARATUS, AND MOVING OBJECT

(71) Applicant: Seiko Epson Corporation, Tokyo (JP)

(72) Inventors: Yusuke Matsuzawa, Chino (JP); Yuji Chino, Suwa (JP)

(73) Assignee: Seiko Epson Corporation, Tokyo (JP)

(21) Appl. No.: 14/096,412

(22) Filed: Dec. 4, 2013

(30) Foreign Application Priority Data
Dec. 11, 2012 (JP) 2012-270077
Dec. 11, 2012 (JP) 2012-270079

(51) Int. Cl. H02N 1/06; G01C 5/06; B81B 7/02

(52) U.S. Cl. CPC H02N 1/06; B81B 7/02; G01C 5/06
USPC 73/384; 310/309

(57) ABSTRACT

A MEMS element includes a substrate and a plurality of resonators which are formed above a first surface of the substrate, the substrate includes at least one flexible portion and at least one non-flexible portion, and resonators corresponding to the flexible portion and the non-flexible portion are disposed.

### BACKGROUND

1. Technical Field

The present invention relates to a Micro Electro Mechanical Systems (MEMS) element, an electronic device, an altimeter, an electronic apparatus, and a moving object.

2. Related Art

In the related art, as a device which detects pressure, a semiconductor pressure sensor disclosed in JP-A-2001-332746 is known. In the semiconductor pressure sensor disclosed in JP-A-2001-332746, a strain sensing element is formed on a silicon wafer, a surface opposite to a strain sensing element formation surface of the silicon wafer is polished, a diaphragm portion is formed by thinning the opposite surface, a strain sensing element detects strain generated in the diaphragm portion which is displaced by pressure, and the detection result is converted to pressure.

However, in the pressure sensor which includes the strain sensing element disclosed in JP-A-2001-332746, thinning of the silicon wafer is required, and thus, it is difficult to integrate the pressure sensor with a semiconductor device (IC) which becomes a calculation unit processing signals from the pressure sensor.

Meanwhile, semiconductor device manufacturing methods and devices for manufacturing micro mechanical systems, so-called a Micro Electro Mechanical Systems (MEMS) elements, have attracted attention. Extremely small various sensors, oscillators, or the like can be obtained by using a MEMS element. In the sensors or the like, a minute vibration element is formed on a substrate using the MEMS technology, and thus, an element, which performs detection of acceleration, generation of a reference signal, or the like using vibration characteristics of the vibration element, can be obtained.

The vibration element is formed using MEMS technology, a pressure sensor, which detects pressure by variation of a vibration frequency of the MEMS vibration element, is configured, and thus, the pressure sensor which is integrated with the IC can be realized. However, in the MEMS element, since the variation of the vibration frequency is also generated by an external factor such as vibration or impact in addition to the pressure to be detected, there is a problem that errors with respect to minute pressure variations easily occur.

### SUMMARY

An advantage of some aspects of the invention is to provide a MEMS element which can configure a pressure sensor capable of measuring correct minute pressure by detecting a variation amount of the vibration frequency due to the external factor and correcting the variation amount of the vibration frequency due to the external factor from a detected pressure value.

An advantage of some aspects of the invention is to solve at least a part of the problems described above, and the invention can be implemented as the following forms or application examples.

### Application Example 1

This application example is directed to a MEMS element including: a substrate; and a plurality of resonators which are formed on a first surface of the substrate. The substrate includes at least one flexible portion and at least one non-flexible portion, and the plurality of resonators include a resonator corresponding to the flexible portion and a resonator corresponding to the non-flexible portion.

According to this application example, bending is generated in the flexible portion by applying external pressure to the flexible portion, and a vibration characteristic of the resonator, that is, a resonant frequency is changed. By deriving a relationship between the external pressure and the change of the frequency characteristic of the resonator, the MEMS element can be used as a sensor which detects the external pressure from the change of the frequency characteristic of the resonator.

On the other hand, the bending due to the external pressure is not generated in the non-flexible portion. However, if disturbance other than the external pressure, for example, an impact force, acceleration, or the like is applied to the MEMS element, the change of the resonant frequency due to the disturbance is generated in both of the resonator disposed in the flexible portion and the resonator disposed in the non-flexible portion. At this time, since the resonant frequency is changed by only the disturbance in the resonator disposed in the non-flexible portion, by subtracting the change amount of the resonant frequency of the resonator disposed in the non-flexible portion from the resonant frequency of the resonator disposed in the flexible portion which is changed by the external pressure and the disturbance, the change of the resonant frequency generated by only the external pressure of the resonator disposed in the flexible portion can be obtained. Accordingly, even in an environment in which disturbances such as impact or acceleration are present, a MEMS element, which is a pressure sensor capable of correctly detecting the pressure value, can be obtained.

### Application Example 2

This application example is directed to the MEMS element according to the application example described above, wherein the MEMS element further includes a closed space portion which is formed on the first surface of the substrate, and the plurality of resonators are disposed in the space portion.

According to this application example, since the plurality of resonators are accommodated in the inner portion of the same space portion, it is possible to suppress differences in the change amount of the resonant frequency of the resonator with respect to the change of air tightness of the space portion from being generated among the plurality of resonators. Accordingly, a MEMS element having high reliability can be obtained.

### Application Example 3

This application example is directed to the MEMS element according to the application example described above, wherein the flexible portion is a bottom portion of a concave portion which is formed on a side of a second surface having a front-rear surface relationship with the first surface of the substrate.

According to this application example, the flexible portion and the non-flexible portion can be easily formed according to presence or absence of the concave portion of the substrate. In addition, since the bottom portion of the concave portion is a thin portion, the thickness of the thin portion can be easily adjusted by adjusting the depth of the concave portion, and it is possible to easily obtain a MEMS element in accordance with the level of external pressure to be detected.

### Application Example 4

This application example is directed to the MEMS element according to the application example described above, wherein the MEMS element further includes a semiconductor device.

According to this application example, since the MEMS element can be manufactured by the same manufacturing apparatus and method as the manufacturing apparatus and method of the semiconductor device, that is, a so-called IC, the MEMS element and the IC can be easily integrated while realizing reduction in manufacturing cost and reduction in environmental load, and thus, a small-sized MEMS element including an oscillation circuit can be obtained.

### Application Example 5

This application example is directed to an electronic device including: a substrate; and a plurality of resonators which are formed on a first surface of the substrate. The substrate includes at least one flexible portion and at least one non-flexible portion. In addition, the plurality of resonators include: a MEMS element which includes a resonator corresponding to the flexible portion and a resonator corresponding to the non-flexible portion; and a holding unit which exposes a side of a second surface having a front-rear surface relationship with the first surface of the substrate of the MEMS element to a pressure variation region and holds the side of the second surface. In addition, at least one flexible portion and at least one non-flexible portion are exposed to the pressure variation region.

According to this application example, bending is generated in the flexible portion by applying external pressure to the flexible portion, and a vibration characteristic of the resonator, that is, a resonant frequency is changed. By deriving a relationship between the external pressure and the change of the frequency characteristic of the resonator, a pressure sensor, which is an electronic device detecting the external pressure from the change of the frequency characteristic of the resonator, can be obtained.

On the other hand, the bending due to the external pressure is not generated in the non-flexible portion. However, if disturbance other than the external pressure, for example, an impact force, acceleration, or the like is applied to the MEMS element, the change of the resonant frequency due to the disturbance is generated in both of the resonator disposed in the flexible portion and the resonator disposed in the non-flexible portion. At this time, since the resonant frequency is changed by only the disturbance in the resonator disposed in the non-flexible portion, by subtracting the change amount of the resonant frequency of the resonator disposed in the non-flexible portion from the resonant frequency of the resonator disposed in the flexible portion which is changed by the external pressure and the disturbance, the change of the resonant frequency generated by only the external pressure of the resonator disposed in the flexible portion can be obtained. Accordingly, even in an environment in which disturbances such as impact or acceleration are present, a pressure sensor, which is an electronic device capable of correctly detecting the pressure value, can be obtained.

### Application Example 6

This application example is directed to the electronic device according to the application example described above, wherein the electronic device further includes a closed space portion which is formed on the first surface of the substrate, and the plurality of resonators are disposed in the space portion.

According to this application example, since the plurality of resonators are accommodated in the inner portion of the same space portion, it is possible to suppress differences in the change amount of the resonant frequency of the resonator with respect to the change of air tightness of the space portion from being generated among the plurality of resonators. Accordingly, a pressure sensor, which is an electronic device that has high reliability and correctly detects the pressure value, can be obtained.

### Application Example 7

This application example is directed to the electronic device according to the application example described above, wherein the flexible portion is a bottom portion of a concave portion which is formed on a side of a second surface having a front-rear surface relationship with the first surface of the substrate.

According to this application example, the flexible portion and the non-flexible portion can be easily formed according to presence or absence of the concave portion of the substrate. In addition, since the bottom portion of the concave portion is a thin portion, the thickness of the thin portion can be easily adjusted by adjusting the depth of the concave portion, and it is possible to obtain an electronic device including a MEMS element in accordance with the level of the external pressure to be detected.

### Application Example 8

This application example is directed to the electronic device according to the application example described above, wherein the electronic device further includes a semiconductor device.

According to this application example, since the MEMS element can be manufactured by the same manufacturing apparatus and method as the manufacturing apparatus and method of a semiconductor device, that is, a so-called IC, the MEMS element and the IC can be easily integrated, and an electronic device which includes a small-sized MEMS element having an oscillation circuit can be obtained.

### Application Example 9

This application example is directed to an electronic apparatus including: a substrate; and a plurality of resonators which are formed on a first surface of the substrate. The substrate includes at least one flexible portion and at least one non-flexible portion. In addition, the plurality of resonators include: a MEMS element which includes a resonator corresponding to the flexible portion and a resonator corresponding to the non-flexible portion; a holding unit which exposes a side of a second surface having a front-rear surface relationship with the first surface of the substrate of the MEMS element to a pressure measurement target region and exposes and holds at least one flexible portion and at least one non-flexible portion in the pressure measurement target region; and a data processing unit which processes measurement data of the MEMS element.

According to this application example, bending is generated in the flexible portion by applying external pressure to the flexible portion, and a vibration characteristic of the resonator, that is, a resonant frequency is changed. By deriving a relationship between the external pressure and the change of the frequency characteristic of the resonator, an electronic apparatus can be obtained, which has an altimeter, which detects the external pressure from the change of the frequency characteristic of the resonator, and which can calculate altitude from the pressure value, as an example.

On the other hand, the bending due to the external pressure is not generated in the non-flexible portion. However, if disturbance other than the external pressure, for example, an impact force, acceleration, or the like is applied to the MEMS element, the change of the resonant frequency due to the disturbance is generated in both of the resonator disposed in the flexible portion and the resonator disposed in the non-flexible portion. At this time, since the resonant frequency is changed by only the disturbance in the resonator disposed in the non-flexible portion, by subtracting the change amount of the resonant frequency of the resonator disposed in the non-flexible portion from the resonant frequency of the resonator disposed in the flexible portion which is changed by the external pressure and the disturbance, the change of the resonant frequency generated by only the external pressure of the resonator disposed in the flexible portion can be obtained. Accordingly, even in an environment in which disturbances such as impact or acceleration are present, an electronic apparatus, which has an altimeter capable of accurately calculating altitude from the correct pressure value, as an example, can be obtained.

### Application Example 10

This application example is directed to the electronic apparatus according to the application example described above, wherein the electronic apparatus further includes a closed space portion which is formed on the first surface of the substrate, and the plurality of resonators are disposed in the space portion.

According to this application example, since the plurality of resonators are accommodated in the inner portion of the same space portion, it is possible to suppress differences in the change amount of the resonant frequency of the resonator with respect to the change of air tightness of the space portion from being generated among the plurality of resonators. Accordingly, an electronic apparatus, which has an altimeter having high reliability and capable of accurately calculating altitude from the correct pressure value, as an example, can be obtained.

### BRIEF DESCRIPTION OF THE DRAWINGS

The invention will be described with reference to the accompanying drawings, wherein like numbers reference like elements.

FIGS. 1A to 1B show a MEMS element according to a first embodiment, FIG. 1A is a schematic cross-sectional view, FIG. 1B is a plan view of a MEMS vibrator portion, and FIG. 1C is a schematic cross-sectional view showing another configuration of a flexible portion.

FIG. 2A is a cross-sectional schematic view showing a steady state of the MEMS element according to the first embodiment and FIG. 2B is a cross-sectional schematic view of the MEMS vibrator for explaining an operation in a pressurized state.

FIG. 3 is a schematic cross-sectional view showing the MEMS element having another configuration.

FIG. 4 is a schematic cross-sectional view showing the MEMS element having still another configuration.

FIGS. 5A to 5C show a MEMS element according to a second embodiment, FIG. 5A is a schematic cross-sectional view, FIG. 5B is a plan view showing a MEMS vibrator portion, and FIG. 5C is a schematic cross-sectional view showing another configuration of a flexible portion.

FIG. 6 is a schematic cross-sectional view showing the MEMS element having another configuration.

FIG. 7 is a schematic cross-sectional view showing the MEMS element having still another configuration.

FIGS. 8A and 8B show an altimeter according to a third embodiment, FIG. 8A is a configuration view, and FIG. 8B is an enlarged view of a C portion shown in FIG. 8A.

FIG. 9 is a flow chart showing a measurement method.

FIG. 10 is a partial cross-sectional view showing the altimeter having another configuration.

FIG. 11 is an outline view showing a moving object according to a fourth embodiment.

### DESCRIPTION OF EXEMPLARY EMBODIMENTS

Hereinafter, embodiments according to the invention will be described with reference to the accompanying drawings.

### First Embodiment

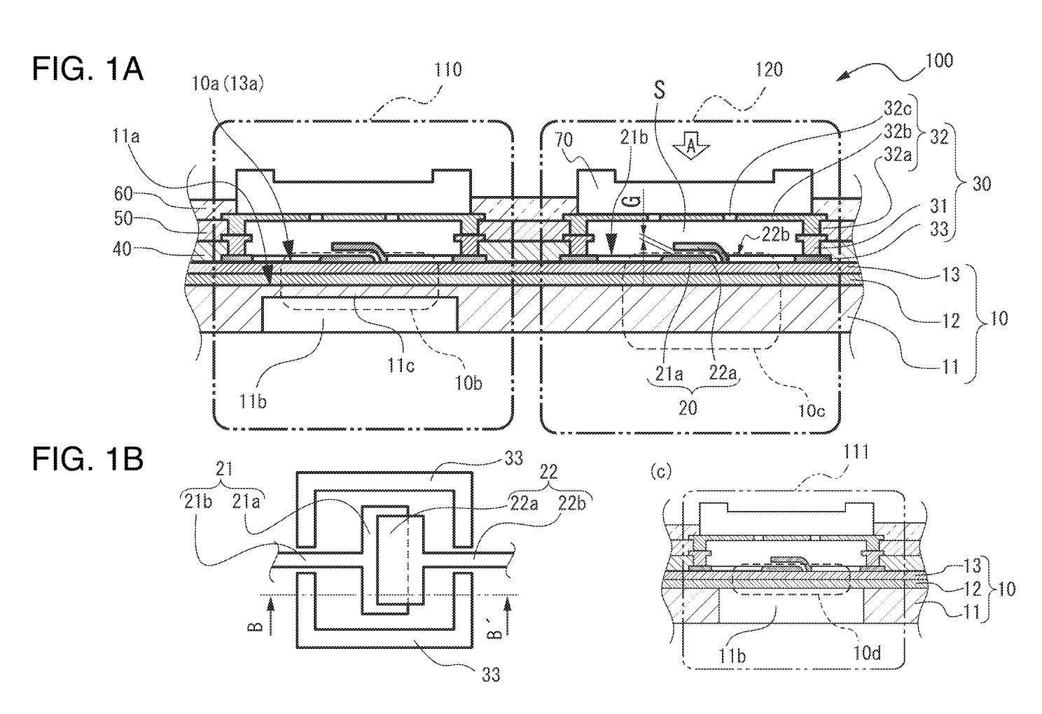

FIGS. 1A to 1C show a MEMS element according to a first embodiment, FIG. 1A is a schematic cross-sectional view, and FIG. 1B is a view when viewed from an A direction of an electrode portion shown in FIG. 1A. Moreover, FIG. 1C is a schematic cross-sectional view showing another configuration of a flexible portion. In addition, FIG. 1A and FIG. 1C are cross-sectional views corresponding to a B-B′ portion shown in FIG. 1B. As shown in FIG. 1A, a MEMS element 100 according to the embodiment includes a substrate 10 configured of a wafer substrate 11, a first oxide film 12 which is formed on a principal surface 11a of the wafer substrate 11, and a nitride film 13 which is formed on the first oxide film 12. The wafer substrate 11 is a silicon substrate and is also used as the wafer substrate 11 which forms a semiconductor device described below, that is, a so-called IC.

A MEMS vibrator 20, which is a resonator, is formed on the principal surface 10a which is a first surface of the substrate 10, that is, a surface 13a of the nitride film 13. As shown in FIG. 1B, the MEMS vibrator 20 is configured of a lower fixed electrode 21a (hereinafter, referred to as a lower electrode 21a) included in a first conductive layer 21 and a movable electrode 22a (hereinafter, referred to as an upper electrode 22a) included in a second conductive layer 22. The first conductive layer 21 and the second conductive layer 22 are formed by patterning conductive polysilicon through photolithography. Moreover, the example, in which the first conductive layer 21 and the second conductive layer 22 use polysilicon, is described in the embodiment. However, the invention is not limited to this.

In the MEMS vibrator 20, a gap G is formed between the lower electrode 21a and the upper electrode 22a, and the gap is a space in which the upper electrode 22a can move. In addition, the MEMS vibrator 20 is formed so as to be accommodated in a space S which is formed on the principal surface 10a of the substrate 10. The space S is formed as follows. After the first conductive layer 21 and the second conductive layer 22 are formed, a second oxide film 40 is formed. In the second oxide film 40, the second conductive layer 22 is formed, and at the same time, a hole, to which an undermost layer 33 is exposed, is formed of polysilicon so as to be connected to the undermost layer 33 of a space wall portion 30 described below, and a first wiring layer 31 is formed by patterning through photolithography.

Moreover, a third oxide film 50 is formed on the second oxide film 40. In the third oxide film 50, a hole, to which a first wiring layer 31 is exposed, is formed, and a second wiring layer 32 is formed by the patterning through the photolithography. The second wiring layer 32 includes: a wall portion 32a which configures the uppermost layer of the space wall portion 30 described below; and a cover portion 32b which configures the space S receiving the MEMS vibrator 20. In addition, the cover portion 32b of the second wiring layer 32 includes an opening 32c for performing release etching on the second oxide film 40 and the third oxide film 50 which are formed in the manufacturing process for forming the space S and are positioned in the region of the space S.

Next, a protective film 60 is formed to expose the opening 32c of the second wiring layer 32, an etchant, which etches the second oxide film 40 and the third oxide film 50, is introduced from the opening 32c, and the space S is formed by the release etching. The space S is a region which is enclosed by the space wall portions 30 which are formed of the undermost layer 33, the first wiring layer 31, and the second wiring layer 32.

The gap G provided in the MEMS vibrator 20 is formed by the release etching when the space S is formed as described above. That is, after the first conductive layer 21 is formed, a fourth oxide film (not shown) is formed on the lower electrode 21a, and the upper electrode 22a is formed on the fourth oxide film. Moreover, the fourth oxide film is removed along with the second oxide film 40 and the third oxide film 50 by the release etching, and thus, the gap G is formed. Moreover, the second oxide film 40 and the third oxide film 50 of the region corresponding to the space S removed by the above-described release etching, and the fourth oxide film are referred to as sacrifice layers.

If the release etching ends and the space S is formed, a coating layer 70 is formed and covers the cover portion 32b of the second wiring layer 32 which is not covered by the protective film 60, and the opening 32c is sealed. Accordingly, the space S is closed.

In this way, the MEMS element 100 is formed. In the MEMS element 100 according to the embodiment, a concave portion 11b is formed on a wafer substrate rear surface 11d of the wafer substrate 11, which becomes a substrate rear surface 10e as a second surface which is a surface opposite to the principal surface 10a of the substrate 10 corresponding to at least one MEMS vibrator. The concave portion 11b is formed, and thus, a thin portion 11c is formed in the region of the principal surface 10a on which the MEMS vibrator 20 is formed. A flexible portion 10b is configured of the thin portion 11c, the first oxide film 12 formed on the thin portion 11c, and the nitride film 13. The MEMS element 100 according to the embodiment includes a first MEMS element 110 which has the flexible portion 10b, and a second MEMS element 120 which does not have the flexible portion 10b, that is, has a non-flexible portion 10c.

In the embodiment, as shown in FIG. 1A, the configuration which includes one first MEMS element 110 and one second MEMS element 120 is exemplified. However, the invention is not limited to this, and the first MEMS element 110 and the second MEMS element 120 may each be provided in plural. By providing a plurality of first MEMS elements 110 and a plurality of second MEMS elements 120, more accurate data can be obtained by, for example, averaging data obtained from the first MEMS elements 110 and the second MEMS elements 120. When a plurality of first MEMS elements 110 and a plurality of second MEMS elements 120 are provided, at least one first MEMS element 110 and at least one second MEMS element 120 may be provided, respectively.

The flexible portion 10b may have the configuration shown in FIG. 1C. As shown in FIG. 1C, in the first MEMS element 111, the concave portion 11b, to which the first oxide film 12 is exposed, is formed in the wafer substrate 11, and a flexible portion 10d may be formed of the first oxide film 12 and the nitride film 13. Moreover, the non-flexible portion 10c in the second MEMS element 120 is not limited to the configuration shown in FIG. 1A, and may have any configuration as long as the substrate 10 of the region corresponding to the MEMS vibrator 20 is not bent or is not easily bent by an external force.

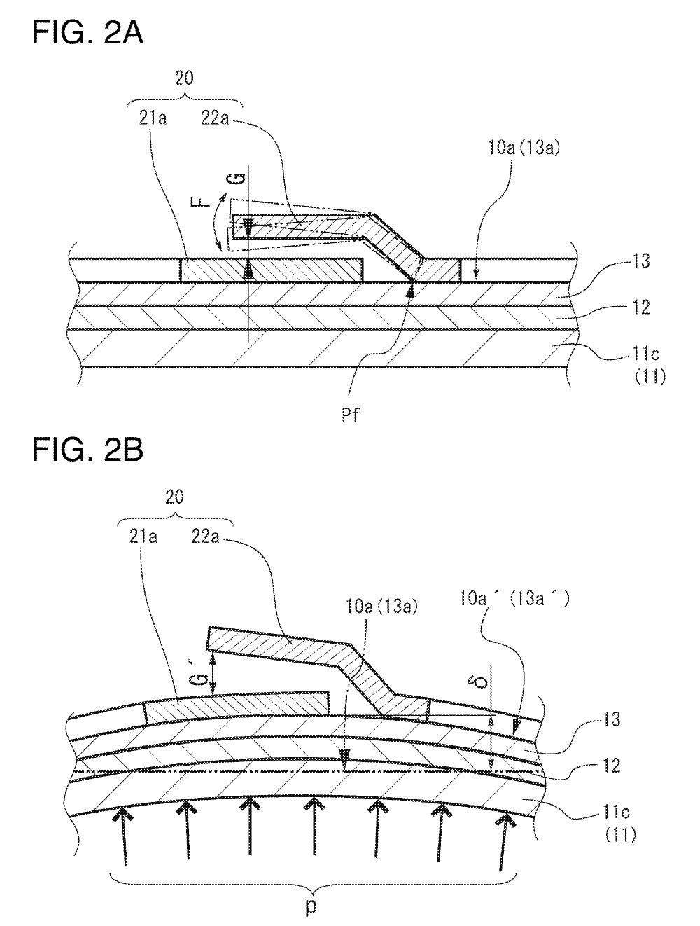

In the MEMS element 100 according to the embodiment, in the first MEMS elements 110 and 111 including the flexible portions 10b and 10d, the bending is generated in the flexible portions 10b and 10d by an external factor, particularly, the external force such as pressure, and thus, vibration frequency characteristics of the MEMS vibrator 20 are changed. This mechanism will be described with reference to FIGS. 2A and 2B. FIG. 2A is an enlarged cross-sectional schematic view of the B-B′ portion shown in FIG. 1B of the MEMS vibrator 20 in a steady state of the first MEMS element 110 shown in FIG. 1A, and FIG. 2B is an enlarged cross-sectional schematic view showing the MEMS vibrator 20 of the first MEMS element 110 in a state where the external force is applied to the steady state shown in FIG. 2A. Moreover, in this example, the first MEMS element 110 is described as an example. However, the first MEMS element 111 is also similar.

As shown in FIG. 2A, in the MEMS vibrator 20 in the steady state, the upper electrode 22a is disposed to be separated from the lower electrode 21a with the gap G. The upper electrode 22a is a cantilever which has a junction point Pf between the principal surface 10a of the substrate 10 and the upper electrode as a fixed point. An electrostatic force, which is generated by electrical charges applied to the lower electrode 21a and the upper electrode 22a, vibrates the upper electrode 22a in an F direction. Moreover, by detecting a change of capacitance of the gap G, the vibration characteristic such as the vibration frequency of the MEMS vibrator 20 can be obtained.

In the first MEMS element 110 including the MEMS vibrator 20 which can be vibrated as described above, as shown in FIG. 2B, pressure P is applied to the concave portion 11b of the wafer substrate 11 as the external force, and stress is applied to the thin portion 11c, the first oxide film 12, and the nitride film 13 which configure the flexible portion 10b. Accordingly, the principal surface 10a of the substrate 10 is deformed and becomes a principal surface 10a′, and bending 8 is generated. As a result, the gap G of the MEMS vibrator is changed to a gap G′ after load and the vibration characteristic of the MEMS vibrator 20 is changed. By deriving a relationship between the external pressure p and the change of the frequency characteristic of the MEMS vibrator 20, the MEMS element 100 can be used as a sensor which detects the external pressure p from the change of the frequency characteristic of the MEMS vibrator 20.

In the first MEMS element 110, the flexible portion 10b is bent by the external pressure p, resonant frequency is changed according to the change of the capacitance of the MEMS vibrator 20, and the value of the pressure p can be obtained. On the other hand, the second MEMS element 120 includes the non-flexible portion 10c, and thus, the bending due to the pressure p is not generated in the non-flexible portion 10c. That is, if disturbance other than the pressure p, for example, an impact force, acceleration, or the like is applied to the MEMS element 100, the change of the resonant frequency due to the disturbance is generated in both of the first MEMS element 110 and the second MEMS element 120. At this time, since the resonant frequency is changed by only the disturbance in the second MEMS element 120, by subtracting the change amount of the resonant frequency of the second MEMS element 120 from the resonant frequency of the first MEMS element 110 which is changed by the pressure p and the disturbance, the change of the resonant frequency generated by only the pressure p of the first MEMS element 110 can be obtained. Accordingly, even in an environment in which disturbances such as impact or acceleration are present, the MEMS element 100, which is a pressure sensor capable of correctly detecting the pressure value, can be obtained.

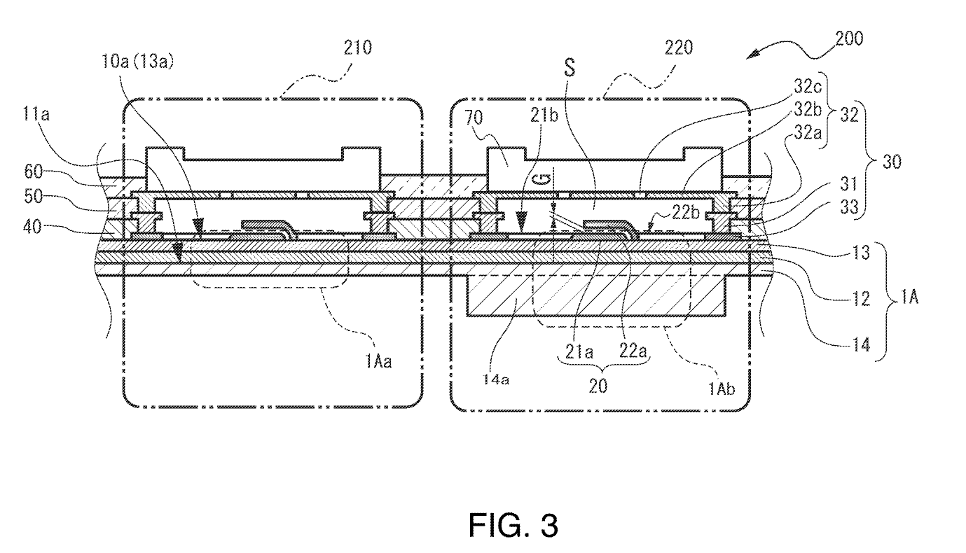

FIG. 3 shows another configuration of the MEMS element 100 according to the first embodiment. With respect to the MEMS element 100 shown in FIGS. 1A to 1C, in a MEMS element 200 shown in FIG. 3, the shapes of the flexible portion 10b included in the first MEMS element 110 and the non-flexible portion 10c included in the second MEMS element 120 are different. As shown in FIG. 3, a substrate 1A, which is configured of a wafer substrate 14, the first oxide film 12, and the nitride film 13, is thinly formed to include a flexible portion 1Aa having flexibility as a basic configuration in a first MEMS element 210. On the other hand, in a second MEMS element 220 which requires inflexibility in the substrate 1A, a convex portion 14a is formed, and thus, the thickness of the second MEMS element is thickened, and a non-flexible portion 1Ab is formed. Moreover, in this example, the convex portion 14a is integrally formed to the wafer substrate 14. However, the convex portion 14a may be configured to be fixed to the wafer substrate 14 as a separate body.

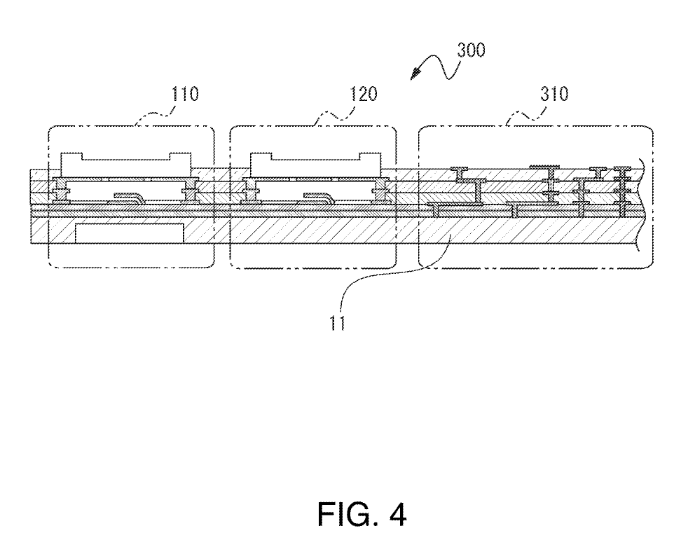

FIG. 4 shows a configuration in which the above-described MEMS element 100 and a semiconductor device are configured in one chip. A MEMS element 300 shown in FIG. 4 includes a configuration in which the first MEMS element 110, the second MEMS element 120, and a semiconductor device 310 are formed in one chip. Since the first MEMS element 110 and the second MEMS element 120 are micro devices which can be manufactured by a semiconductor manufacturing method using a semiconductor manufacturing apparatus, the semiconductor device 310 can be easily formed on the same wafer substrate 11 as the first MEMS element 110 and the second MEMS element 120. The semiconductor device 310 includes a transmitting circuit which drives the first MEMS element 110 and the second MEMS element 120, a calculation circuit which calculates the frequency variation of the first MEMS element 110 and the second MEMS element 120, or the like. As shown in the MEMS element 300, the semiconductor device 310 is formed in one chip along with the first MEMS element 110 and the second MEMS element 120, and thus, a small-sized sensor device can be obtained. Moreover, as described above, since the semiconductor device 310 and the MEMS elements 110 and 120 can be manufactured by the same semiconductor manufacturing apparatus and the same semiconductor manufacturing method, reduction in the manufacturing cost and reduction in environmental load can be realized.

### Second Embodiment

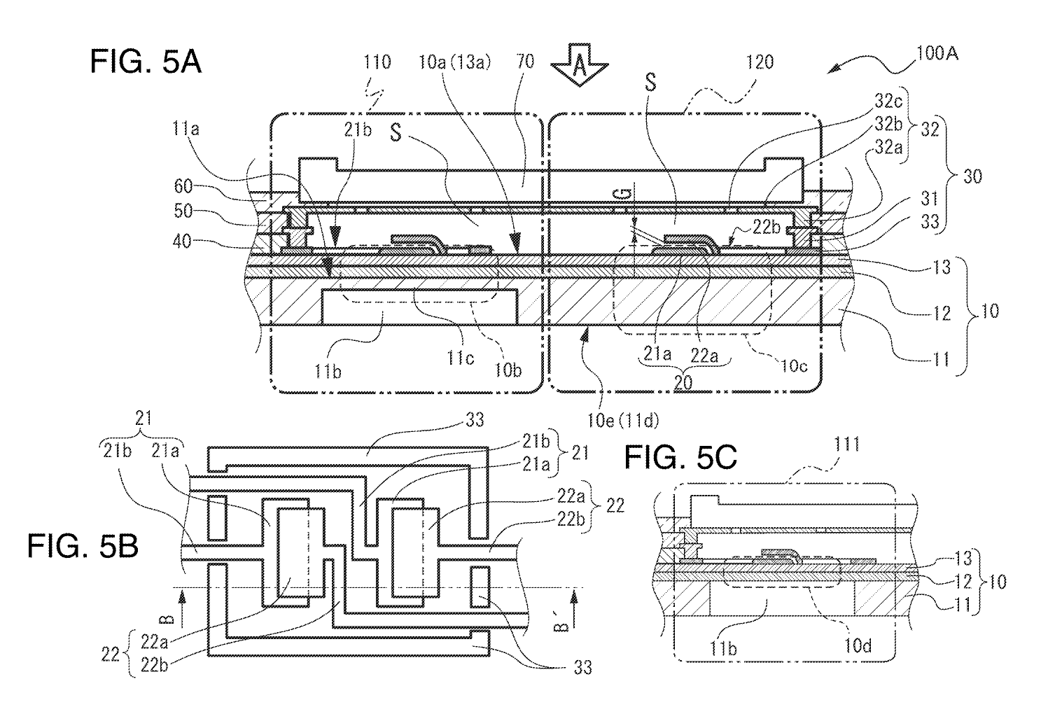

FIGS. 5A to 5C show a MEMS element according to a second embodiment, FIG. 5A is a schematic cross-sectional view, and FIG. 5B is a view when viewed from an A direction of an electrode portion shown in FIG. 5A. Moreover, FIG. 5C is a schematic cross-sectional view showing another configuration of a flexible portion. In addition, FIG. 5A and FIG. 5C are cross-sectional views corresponding to a B-B′ portion shown in FIG. 5B. As shown in FIG. 5A, a MEMS element 100A according to the embodiment includes the substrate 10 configured of the wafer substrate 11, the first oxide film 12 which is formed on the principal surface 11a of the wafer substrate 11, and the nitride film 13 which is formed on the first oxide film 12. The wafer substrate 11 is a silicon substrate and is also used as the wafer substrate 11 which forms a semiconductor device described below, that is, a so-called IC.

In the embodiment, two sets of MEMS vibrators 20, which are resonators, are formed on the principal surface 10a which is a first surface of the substrate 10, that is, on the surface 13a of the nitride film 13. Moreover, the formed MEMS vibrators 20 are not limited to two sets, and a plurality of sets, which are two or more sets, may be provided. As shown in FIG. 5B, the MEMS vibrator 20 is configured of the lower fixed electrode 21a (hereinafter, referred to as a lower electrode 21a) included in the first conductive layer 21 and the movable electrode 22a (hereinafter, referred to as an upper electrode 22a) included in the second conductive layer 22. Also as shown in FIG. 5B, the first conductive layer 21 includes the lower electrode 21a and a first wiring portion 21b which is connected to an external wiring (not shown). Moreover, the second conductive layer 22 includes the upper electrode 22a and a second wiring portion 22b which is connected to the external wiring (not shown). The first conductive layer 21 and the second conductive layer 22 are formed by patterning conductive polysilicon through photolithography. Moreover, the example, in which the first conductive layer 21 and the second conductive layer 22 use polysilicon, is described in the embodiment. However, the invention is not limited to this.

In the MEMS vibrator 20, the gap G is formed between the lower electrode 21a and the upper electrode 22a, and the gap is a space in which the upper electrode 22a can move. In addition, two sets of MEMS vibrators 20 are formed so as to be accommodated in the space S which is formed on the principal surface 10a of the substrate 10. The space S is formed as follows. After the first conductive layer 21 and the second conductive layer 22 are formed, the second oxide film 40 is formed. In the second oxide film 40, the second conductive layer 22 is formed, and at the same time, the hole, to which the undermost layer 33 is exposed, is formed of polysilicon so as to be connected to the undermost layer 33 of the space wall portion 30 described below, and the first wiring layer 31 is formed by patterning through photolithography.

Moreover, the third oxide film 50 is formed on the second oxide film 40. In the third oxide film 50, a hole, to which the first wiring layer 31 is exposed, is formed, and the second wiring layer 32 is formed by the patterning through the photolithography. The second wiring layer 32 includes the wall portion 32a which configures the uppermost layer of the space wall portion 30 described below, and the cover portion 32b which configures the space S receiving the MEMS vibrator 20. In addition, the cover portion 32b of the second wiring layer 32 includes the opening 32c for performing release etching on the second oxide film 40 and the third oxide film 50 which are formed in the manufacturing process for forming the space S and are positioned in the region of the space S.

Next, the protective film. 60 is formed to expose the opening 32c of the second wiring layer 32, the etchant, which etches the second oxide film 40 and the third oxide film 50, is introduced from the opening 32c, and the space S is formed by the release etching. The space S is the region which is enclosed by the space wall portions 30 which are formed of the undermost layer 33, the first wiring layer 31, and the second wiring layer 32.

The gap G provided in the MEMS vibrator 20 is formed by the release etching when the space S is formed as described above. That is, after the first conductive layer 21 is formed, the fourth oxide film (not shown) is formed on the lower electrode 21a, and the upper electrode 22a is formed on the fourth oxide film. Moreover, the fourth oxide film is removed along with the second oxide film 40 and the third oxide film 50 by the release etching, and thus, the gap G is formed. Moreover, the second oxide film 40 and the third oxide film 50 of the region corresponding to the space S removed by the above-described release etching, and the fourth oxide film are referred to as sacrifice layers.

If the release etching ends and the space S is formed, a coating layer 70 is formed and covers the cover portion 32b of the second wiring layer 32 which is not covered by the protective film 60, and the opening 32c is sealed. Accordingly, the space S is closed.

In this way, the MEMS element 100A is formed. In the MEMS element 100A according to the embodiment, the concave portion 11b is formed on the wafer substrate rear surface lid of the wafer substrate 11, which becomes the substrate rear surface 10e as the second surface which is a surface opposite to the principal surface 10a of the substrate 10 corresponding to at least one MEMS vibrator 20. The concave portion 11b is formed, and thus, the thin portion 11c is formed in the region of the principal surface 10a on which the MEMS vibrator 20 is formed. Here, the thin portion 11c is a bottom portion of the concave portion 11b. The flexible portion 10b is configured of the thin portion 11c, the first oxide film 12 formed on the thin portion 11c, and the nitride film 13. The MEMS element 100A according to the embodiment includes the first MEMS element portion 110 which has the flexible portion 10b, and the second MEMS element portion 120 which does not have the flexible portion 10b, that is, which has the non-flexible portion 10c. In addition, the MEMS vibrator 20 configuring the first MEMS element portion 110 and the MEMS vibrator 20 configuring the second MEMS element portion 120 are accommodated in the inner portion of the space S.

In the embodiment, as shown in FIG. 5A, the configuration which includes one first MEMS element portion 110 and one second MEMS element portion 120 is exemplified. However, the invention is not limited to this, and the first MEMS element portion 110 and the second MEMS element portion 120 may each be provided in plural. By providing a plurality of first MEMS element portions 110 and a plurality of second MEMS element portions 120, more accurate data can be obtained by, for example, averaging data obtained from the first MEMS element portions 110 and the second MEMS element portions 120. When a plurality of first MEMS element portions 110 and a plurality of second MEMS element portions 120 are provided, at least one first MEMS element portion 110 and at least one second MEMS element portion 120 may be provided.

The flexible portion 10b may have the configuration shown in FIG. 5C. As shown in FIG. 5C, in the first MEMS element portion 111, the concave portion 11b, to which the first oxide film 12 is exposed, is formed in the wafer substrate 11, and the flexible portion 10d may be formed of the first oxide film 12 and the nitride film 13. Moreover, the non-flexible portion 10c in the second MEMS element portion 120 is not limited to the configuration shown in FIG. 5A, and may have any configuration as long as the substrate 10 of the region corresponding to the MEMS vibrator 20 is not bent or is not easily bent by an external force.

In the MEMS element 100A according to the embodiment, in the first MEMS element portions 110 and 111 including the flexible portions 10b and 10d, the bending is generated in the flexible portions 10b and 10d by an external factor, particularly, the external force such as pressure, and thus, vibration frequency characteristics of the MEMS vibrator 20 are changed. This mechanism is similar to the mechanism described with reference to FIGS. 2A and 2B in the above-described first embodiment, and thus, the descriptions thereof are omitted in this embodiment. However, by deriving a relationship between an external pressure and the change of the frequency characteristic of the MEMS vibrator 20, the MEMS element 100A can be used as a sensor which detects the external pressure from the change of the frequency characteristic of the MEMS vibrator 20. In addition, similar to the first embodiment, even in an environment in which disturbances such as impact or acceleration are present, the MEMS element 100A, which is a pressure sensor capable of correctly detecting the pressure value, can be obtained.

Moreover, the MEMS vibrator 20, which includes the first MEMS element portion 110 and the second MEMS element portion 120, is accommodated in the inner portion of the same space S, it is possible to suppress occurrence of differences in the change amounts between the resonant frequency of the first MEMS element portion 110 and the resonant frequency of the second MEMS element portion 120 with respect to the change of air tightness of the space S. That is, in the inner portion of the space S, a so-called air-tight vacuum, which excludes oxygen molecules and nitrogen molecules that make up the air which impedes vibration in the vibration direction F (refer to FIG. 2A) of the upper electrode 22a of the MEMS vibrator 20, is maintained. However, with lapse of time, there is a concern that a gas component in the environment, in which the MEMS element 100A is used, may slightly penetrate into the inner portion of the space S, and thus, the vibration of the upper electrode 22a will be disturbed by the molecules of the gas component penetrating into the space S. As a result, a variation of the resonant frequency occurs.

However, in the MEMS element 100A according to the embodiment, the MEMS vibrators 20 included in the first MEMS element portion 110 and the second MEMS element portion 120 are accommodated in the inner portion of the same space S, and thus, even when the gas component penetrates into the space S, the influence of the vibration of the upper electrode 22a included in the first MEMS element portion 110 and the influence of the vibration of the upper electrode 22a included in the second MEMS element portion 120 become the same as each other. Accordingly, a difference of the change amounts in the resonant frequency due to the penetrating gas component does not easily occur, and even in an environment in which disturbances such as impact or acceleration are present, the MEMS element 100A, which is a pressure sensor capable of correctly detecting the pressure value over long time, can be obtained.

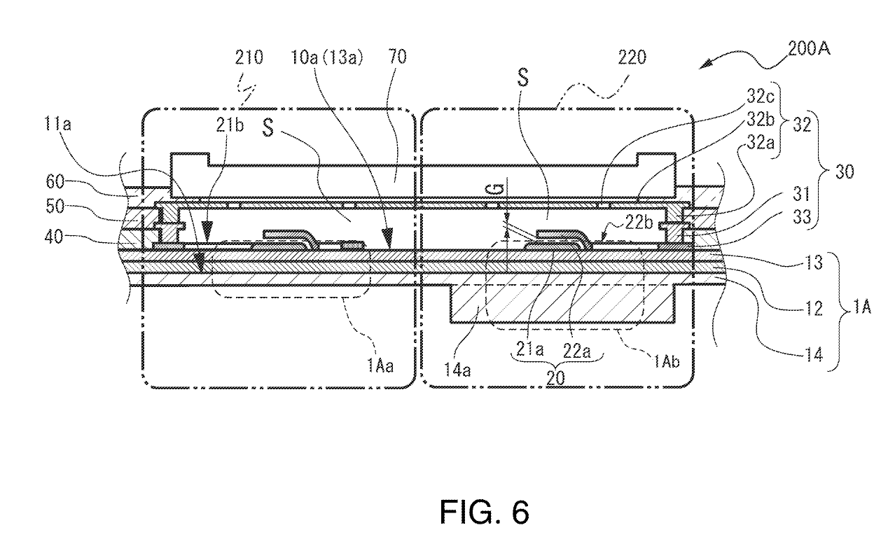

FIG. 6 is another configuration of the MEMS element 100A according to the second embodiment. With respect to the MEMS element 100A shown in FIGS. 5A to 5C, in a MEMS element 200A shown in FIG. 6, the shapes of the flexible portion 10b included in the first MEMS element portion 110 and the non-flexible portion 10c included in the second MEMS element portion 120 are different. As shown in FIG. 6, the substrate 1A, which is configured of the wafer substrate 14, the first oxide film 12, and the nitride film 13, is thinly formed to include the flexible portion 1Aa having flexibility as a basic configuration in the first MEMS element portion 210. On the other hand, in the second MEMS element portion 220 which requires inflexibility in the substrate 1A, the convex portion 14a is formed, and thus, the thickness of the second MEMS element is thickened, and the non-flexible portion 1Ab is formed. Moreover, in this example, the convex portion 14a is integrally formed to the wafer substrate 14. However, the convex portion 14a may be configured to be fixed to the wafer substrate 14 as a separate body.

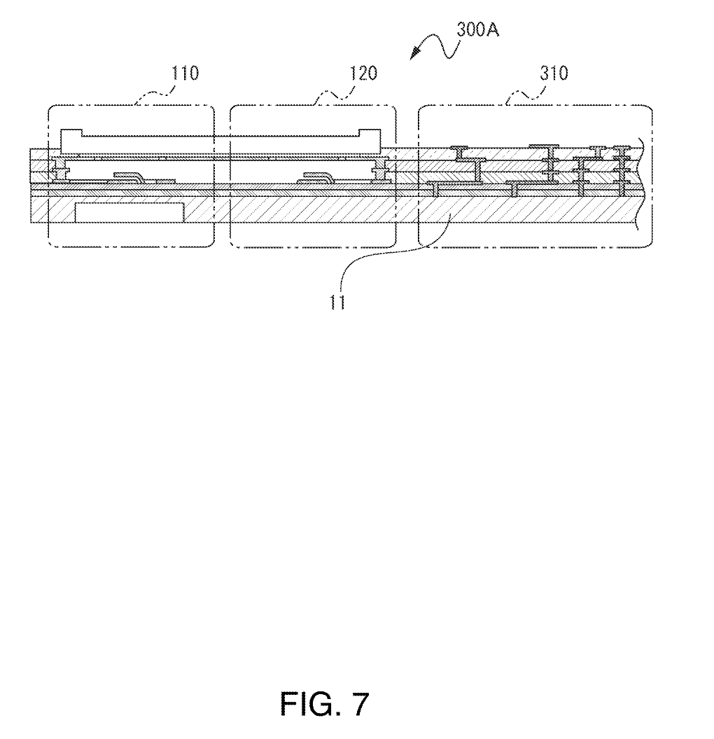

FIG. 7 shows a configuration in which the above-described MEMS element 100A and a semiconductor device are configured in one chip. A MEMS element 300A shown in FIG. 7 includes a configuration in which the first MEMS element portion 110, the second MEMS element portion 120, and the semiconductor device 310 are formed in one chip. Since the first MEMS element portion 110 and the second MEMS element portion 120 are micro devices which can be manufactured by a semiconductor manufacturing method using a semiconductor manufacturing apparatus, the semiconductor device 310 can be easily formed on the same wafer substrate 11 as the first MEMS element portion 110 and the second MEMS element portion 120. The semiconductor device 310 includes the transmitting circuit which drives the first MEMS element portion 110 and the second MEMS element portion 120, the calculation circuit which calculates the frequency variation of the first MEMS element portion 110 and the second MEMS element portion 120, or the like. In the MEMS element 300A shown in FIG. 7, the semiconductor device 310 is formed in one chip along with the first MEMS element portion 110 and the second MEMS element portion 120, and thus, a small-sized sensor device can be obtained. Moreover, as described above, since the semiconductor device 310 and the MEMS element portions 110 and 120 can be manufactured by the same semiconductor manufacturing apparatus and the same semiconductor manufacturing method, reduction in the manufacturing cost and reduction in environmental load can be realized.

### Third Embodiment

As a third embodiment, an altimeter will be described with reference to the drawings. The altimeter according to the third embodiment is one form of an electronic apparatus including a pressure sensor which is an electronic device having the MEMS element 300 according to the first embodiment. In addition, in the description of the altimeter according to the third embodiment, an example of the configuration including the MEMS element 300 according to the first embodiment is described. However, the MEMS elements 100 and 200 according to the first embodiment, or the MEMS elements 100A, 200A, and 300A according to the second embodiment may be adopted.

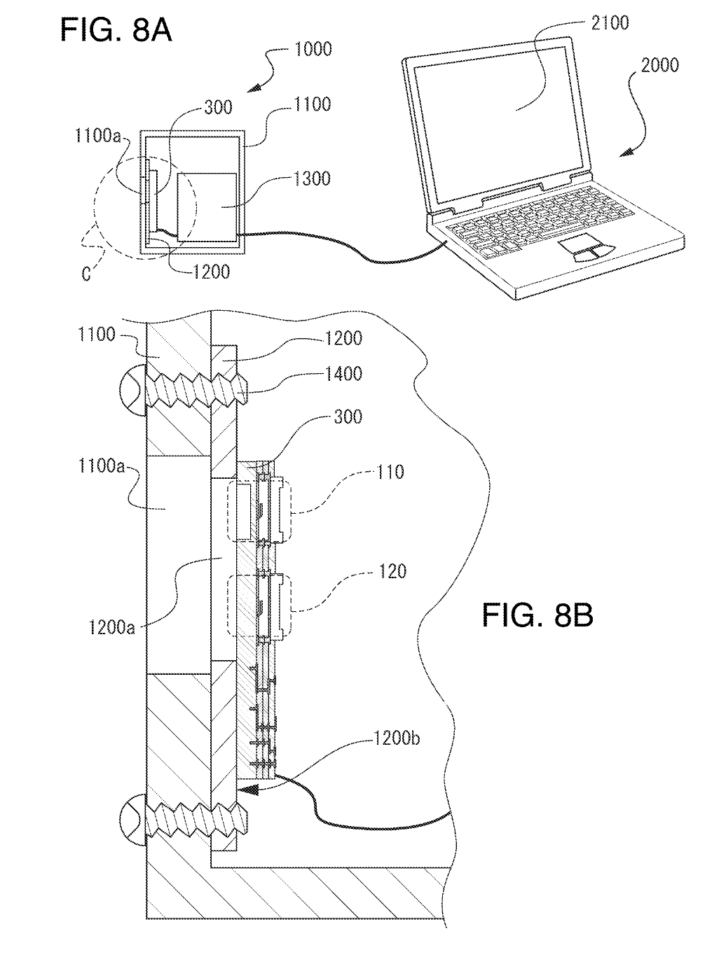

As shown in FIG. 8A, an altimeter 1000, which is the electronic apparatus according to the third embodiment, includes the MEMS element 300 according to the first embodiment, an element fixation frame 1200 which is a holding unit mounted on a housing 1100 to hold the MEMS element 300, and a calculation unit 1300 which calculates the data signal obtained from the MEMS element 300 to altitude data in the housing 1100. In the housing 1100, an opening 1100a is provided, through which the flexible portion 10b of the first MEMS element 110 and the non-flexible portion 10c of the second MEMS element 120 (refer to FIGS. 1A to 1C and FIG. 4), which are included in the MEMS element 300, can be ventilated to the atmosphere.

A C portion shown in FIG. 8A, that is, the detail in the cross-section of the mounting portion of the MEMS element 300 is shown in FIG. 8B. As shown in FIG. 8B, the flexible portion 10b of the first MEMS element 110 and the non-flexible portion 10c of the second MEMS element 120 are disposed to be exposed to the opening 1100a side. Moreover, the element fixation frame 1200 also includes a through hole 1200a, and the through hole 1200a is also disposed so that the flexible portion 10b of the first MEMS element 110 and the non-flexible portion 10c of the second MEMS element 120 are exposed.

The element fixation frame 1200 and the MEMS element 300 are joined to a joint surface 1200b of the element fixation frame 1200 by a unit such as adhesive. The element fixation frame 1200, to which the MEMS element 300 is fixed, is mounted on the housing 1100 by a screw 1400. Moreover, the fixation method of the element fixation frame 1200 to the housing is not limited to the screw 1400, and a fixation unit such as adhesive may be used.

The altimeter 1000 detects pressure of the atmosphere (hereinafter, referred to as atmospheric pressure) as the pressure variation region which applied to the flexible portion 10b of the first MEMS element 110 and the non-flexible portion 10c of the second MEMS element 120 which are ventilated through the opening 1100a of the housing 1100 and the through hole 1200a of the element fixation frame 1200, and measures altitude. However, the environment, in which the altimeter 1000 is used, is not necessarily a static environment. That is, the altimeter is used in a dynamic environment such as acceleration due to movement or acceleration due to impact. Even in the dynamic environment, the altimeter 1000 according to the embodiment can correctly detect the altitude.

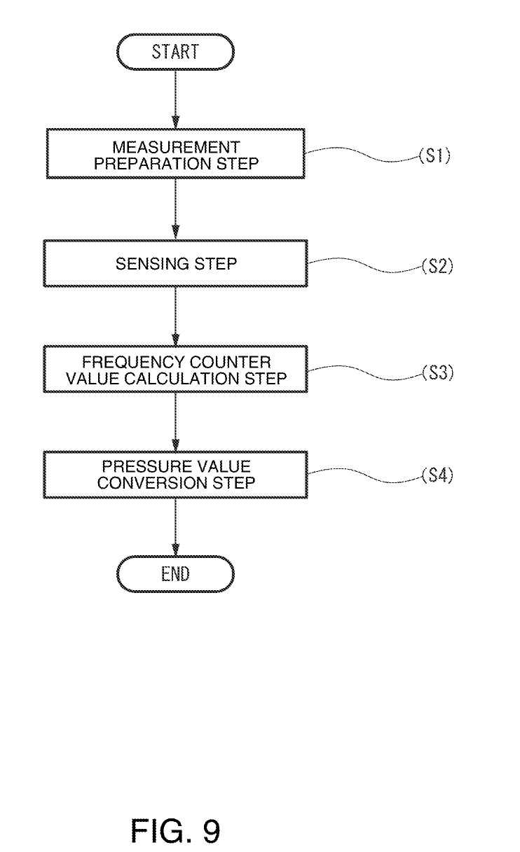

Hereinafter, an outline of an altitude measurement method using the altimeter 1000 according to the embodiment will be described. FIG. 9 is a flowchart showing the altitude measurement method.

### Measurement Preparation Step

First, in a measurement preparation step (S1), a power supply is turned on, and an initial adjustment is performed if necessary. Accordingly, transmission frequencies of the first MEMS element 110 and the second MEMS element 120 are adjusted to F (MHz), the measurement preparation step (S1) ends, and it proceeds to a sensing step.

### Sensing Step

In the sensing step (S2), the flexible portion 10b and the non-flexible portion 10c receive the atmospheric pressure ventilated to the MEMS element 300, and sensing of the atmospheric pressure is performed. In the sensing step (S2), the transmission frequencies of the first MEMS element 110 and the second MEMS element 120 generate the change due to the bending by the atmospheric pressure of the flexible portion 10b and the non-flexible portion 10c, and the change due to the impact force or movement acceleration of dynamic external factors, or the like. Here, in the sensing step (S2), the transmission frequency of the first MEMS element 110 is referred to as a first transmission frequency f1 (MHz), and the transmission frequency of the second MEMS element 120 is referred to as a second transmission frequency f2 (MHz). In the second MEMS element 120 which outputs the second transmission frequency f2, since the MEMS vibrator 20 is formed on the region of the non-flexible portion 10c, the bending of the substrate 10 in the region of the MEMS vibrator 20 due to the atmospheric pressure is not generated. Accordingly, the second transmission frequency f2 is a frequency in which the change due to the dynamic external factors is generated.

On the other hand, since the flexible portion 10b is provided in the first MEMS element 110, the bending is generated in the flexible portion 10b by the change of the atmospheric pressure, and thus, the change of transmission frequency is generated. Moreover, simultaneously, since the change of the transmission frequency due to the dynamic external factors is also generated, in the first transmission frequency f1, the frequency changes are generated due to the atmospheric pressure change and the dynamic external factors. The first transmission frequency f1 and the second transmission frequency f2 obtained in this way proceed to a subsequent frequency counter value calculation step.

### Frequency Counter Value Calculation Step

In the frequency counter value calculation step (S3), in the calculation unit 1300 included in the altimeter 1000, Δf is obtained by subtracting the second transmission frequency f2 from the first transmission frequency f1. That is, Δf=f1−f2 is satisfied. The obtained Δf is a frequency variation amount which subtracts the frequency variation amount due to the dynamic external factors from the first transmission frequency f1, that is, the frequency variation amount due to the atmospheric pressure change.

### Pressure Value Conversion Step

The Δf obtained by the frequency counter value calculation step (S3) is processed in a pressure value conversion step (S4) which converts the Δf to a pressure value. In the pressure value conversion step (S4), in a storage unit (not shown) included in the calculation unit 1300 of the altimeter 1000, Δf is converted to a pressure value according to a conversion table which converts Δf to the pressure value in advance. That is, the conversion table is called from the storage unit, and the pressure value on the table, which coincides with or approximately coincides with Δf obtained in the frequency counter value calculation step, is selected and output. Moreover, the conversion from the pressure value to the altitude is calculated by a conversion expression and is output.

The output altitude data is sent to a personal computer 2000 (hereinafter, referred to as a PC 2000) including a display unit 2100 shown in FIG. 8A, and is display on the display unit 2100 of the PC 2000. At this time, various data processes such as storage of the altitude data, graphing, or display to map data can be performed by the processing software included in the PC 2000. Moreover, instead of the PC 2000, a data processor, a display unit, an external operation unit, or the like may be included in the altimeter 1000.

The second MEMS element 120 is provided in the altimeter 1000 according to the third embodiment, the transmission frequency of the MEMS vibrator 20 due to the acceleration of the movement, the impact force, and the like which are dynamic external factors other than the pressure variation is detected in the measurement of the altitude by the pressure variation, a transmission frequency component due to the pressure variation is derived from the transmission frequency of the first MEMS element 110, and the altitude data which is converted from a correct pressure value or a pressure value can be obtained.

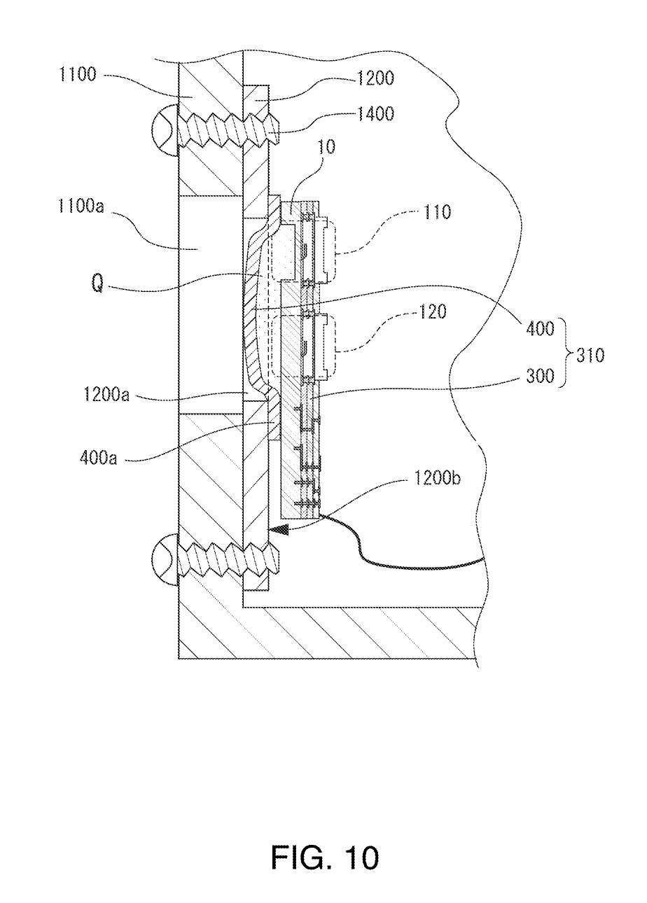

FIG. 10 shows another configuration of the MEMS element 300 which is included in the altimeter 1000 according to the third embodiment. FIG. 10 shows the C portion of FIG. 8A of the altimeter 1000 shown in FIG. 8A. As shown in FIG. 10, in the MEMS element 300, a flexible film 400 having flexibility and air tightness is fixed to the MEMS element 300. For example, as the flexible film 400, a material such as a fluororesin or a synthetic rubber having elasticity and small gas permeability or a metal thin film is preferable.

The flexible film 400 is disposed to cover the flexible portion 10b of the first MEMS element 110 and the non-flexible portion 10c of the second MEMS element 120, and is fixed to the substrate 10 by a flange portion 400a. At this time, for example, gas such as air or inert gas is filled in a space Q (shown in a dotted hatching section) which is formed by the substrate 10 and the flexible film 400, and the space is formed as a pressure vibration region. The MEMS element 300 having the flexible film 400 is fixed to the element fixation frame 1200 and is mounted on the housing 1100.

Since the MEMS element 300 includes the flexible film 400, it is possible to prevent foreign matters, dust, or the like from being attached to the MEMS elements 110 and 120 from the outside, and the MEMS elements can be cleanly maintained, and thus, stable performance of the altimeter can be obtained. In addition, even when the external environment of the flexible film 400 is liquid, corrosion gas, or the like, damage to the MEMS element 300 can be suppressed.

### Fourth Embodiment

A navigation system which is an electronic apparatus having the MEMS elements 100, 200, 300, 100A, 200A, and 300A according to the first embodiment and the second embodiment or the altimeter 1000 according to the third embodiment, and a vehicle which is an aspect of a moving object on which the navigation system is mounted will be described. Moreover, in the embodiment, an example in which the MEMS element 300 according to the first embodiment is adopted is described.

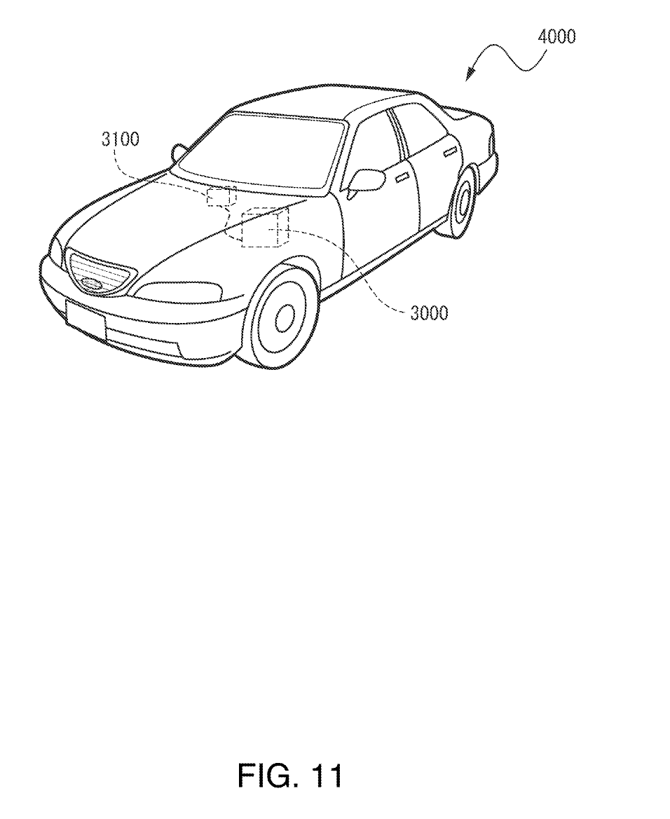

FIG. 11 is an outline view of a vehicle 4000 which is the moving object including the navigation system 3000 as the electronic apparatus. The navigation system 3000 includes map information (not shown), a position information acquisition unit from a Global Positioning System (GPS), a self-contained navigation unit configured of a gyro sensor, an acceleration sensor, and vehicle speed data, and the altimeter 1000 according to the third embodiment, and displays the information in a predetermined position or road information on a display unit 3100 disposed at a position which can be viewed by a driver.

Since the altimeter 1000 is included in the navigation system 3000 in the vehicle 4000 shown in FIG. 11, altitude information can be obtained in addition to the obtained positional information. For example, when the vehicle runs on an elevated road having approximately the same position as a general road in the positional information, in a case where the altitude information is not provided, whether or not the vehicle runs on the general road or an elevated road cannot be determined by the navigation system, and the information of the general road is supplied to the driver as preferential information. Accordingly, since the altitude information can be obtained by the altimeter 1000 in the navigation system 3000 according to the embodiment, an altitude change is detected according to the vehicle entering from the general road to the elevated road, and thus, the navigation information in the running state of the elevated road can be supplied to the driver.

Moreover, in the navigation system 3000 including the vehicle 4000 according to the embodiment, with respect to the impact force due to vibration which is frequently applied, acceleration and deceleration, or acceleration due to the change of direction, minute pressure variation can be detected by subtracting the frequency variation amount obtained by the second MEMS element 120 shown in FIGS. 1A to 1C from the frequency variation of the first MEMS element 110. That is, the vehicle 4000 including the navigation system 3000, in which correct altitude data is obtained with respect to a small altitude change, can be obtained.

In addition, it is possible to configure a small-sized pressure detection apparatus by the MEMS elements 100 and 200 according to the first embodiment, and a drive system of oil pressure or air pressure can be easily incorporated to the vehicle 4000. Accordingly, observation of the pressure in the apparatus and control data can be easily obtained.

The entire disclosure of Japanese Patent Application No. 2012-270077, filed Dec. 11, 2012 and No. 2012-270079, filed Dec. 11, 2012 are expressly incorporated by reference herein.

What is claimed is:

1. A MEMS element comprising:
a substrate; and
a plurality of resonators which are formed above a first surface of the substrate,
wherein the substrate includes at least one flexible portion and at least one non-flexible portion, and
wherein the plurality of resonators include a resonator corresponding to the flexible portion and a resonator corresponding to the non-flexible portion.

2. The MEMS element according to claim 1, further comprising:
a closed space portion which is formed above the first surface of the substrate,
wherein the plurality of resonators are disposed in the space portion.

3. The MEMS element according to claim 1,
wherein the flexible portion is a bottom portion of a concave portion which is formed above a side of a second surface having a front-rear surface relationship with the first surface of the substrate.

4. The MEMS element according to claim 1, further comprising a semiconductor device.

5. An electronic device comprising:
a substrate; and
a plurality of resonators which are formed above a first surface of the substrate,
wherein the substrate includes at least one flexible portion and at least one non-flexible portion,
wherein the plurality of resonators include:
a MEMS element which includes a resonator corresponding to the flexible portion and a resonator corresponding to the non-flexible portion; and
a holding unit which exposes a side of a second surface having a front-rear surface relationship with the first surface of the substrate of the MEMS element to a pressure variation region and holds the side of the second surface, and
wherein at least one flexible portion and at least one non-flexible portion are exposed to the pressure variation region.

6. The electronic device according to claim 5, further comprising:
a closed space portion which is formed above the first surface of the substrate,
wherein the plurality of resonators are disposed in the space portion.

7. The electronic device according to claim 5,
wherein the flexible portion is a bottom portion of a concave portion which is formed above a side of a second surface having a front-rear surface relationship with the first substrate of the substrate.

8. The electronic device according to claim 5, further comprising a semiconductor device.

9. An electronic apparatus comprising:
a substrate; and
a plurality of resonators which are formed above a first surface of the substrate,
wherein the substrate includes at least one flexible portion and at least one non-flexible portion,
wherein the plurality of resonators include:
a MEMS element which includes a resonator corresponding to the flexible portion and a resonator corresponding to the non-flexible portion;
a holding unit which exposes a side of a second surface having a front-rear surface relationship with the first surface of the substrate of the MEMS element to a pressure measurement target region, and exposes and holds at least one flexible portion and at least one non-flexible portion in the pressure measurement target region; and
a data processing unit which processes measurement data of the MEMS element.

10. The electronic apparatus according to claim 9, further comprising:
a closed space portion which is formed above the first surface of the substrate,
wherein the plurality of resonators are disposed in the space portion.
